(19) United States
(12) Patent Application Publication
(10) Pub. No.: US 2026/0308803 A1
(43) Pub. Date: Oct. 8, 2026

(54) Dynamic Seal Deposition Apparatus for Epitaxy

(71) Applicant: Atomic Nano Materials and Equipment Co., Ltd., Nanjing, Jiangsu (CN)

(72) Inventors: Jin Zheng, Nanjing, Jiangsu (CN); Cheng Yao, Nanjing, Jiangsu (CN); Jiayue Tao, Nanjing, Jiangsu (CN)

(21) Appl. No.: 19/485,008

(22) PCT Filed: Oct. 27, 2023
(86) PCT No.: PCT/CN2023/127005

§ 371 Date: Nov. 17, 2025

(30) Foreign Application Priority Data
May 16, 2023 (CN) 202310550073.7

(51) Int. Cl. C30B 25/08; C30B 25/10; C30B 25/12

(52) U.S. Cl. CPC C30B 25/08; C30B 25/10; C30B 25/12

(57) ABSTRACT

The present disclosure provides a dynamic sealing deposition apparatus for epitaxy, relating to the field of semiconductor equipment. The dynamic sealing deposition device for epitaxy comprises a base plate, and a positioning adjustment mechanism is disposed above the base plate. The positioning adjustment mechanism is configured for horizontal positioning adjustment. A lifting and rotating mechanism is provided above the positioning adjustment mechanism. A process chamber is provided above the lifting and rotating mechanism. A holding and ejecting mechanism is provided in the process chamber. The lifting and rotating mechanism is configured for lifting and rotating the holding and ejecting mechanism. The dynamic sealing deposition apparatus for epitaxy solves the technical problems of poor deposition uniformity and poor deposition quality in prior art deposition equipment.

The present disclosure claims priority to Chinese patent application No. 202310550073.7 filed on May 16, 2023, and the entire contents of which are incorporated herein by reference.

### FIELD OF THE INVENTION

The present disclosure relates to the field of semiconductor equipment, and in particular to a dynamic sealing deposition apparatus for epitaxy.

### BACKGROUND OF THE INVENTION

Epitaxial device is a deposition device widely used in semiconductor processing equipment, and its coating process requires a vacuum environment. Existing epitaxial device has difficulty ensuring that wafers are deposited in the center of the process chamber during installation and debugging, resulting in poor deposition uniformity. Furthermore, when there is a deviation in the deposition position of the wafer, it is impossible to adjust the deposition position of the wafer to achieve optimal deposition effect.

### SUMMARY OF THE INVENTION

The present disclosure provides a dynamic sealing deposition apparatus for epitaxy, including a base plate, a positioning adjustment mechanism is provided above the base plate, a lifting and rotating mechanism is provided above the positioning adjustment mechanism, a magnetic fluid dynamic seal is provided above the lifting and rotating mechanism, a process chamber is provided above the magnetic fluid dynamic seal, a holding and ejecting mechanism is provided in the process chamber, the positioning adjustment mechanism includes an X-axis adjustment plate, a Y-axis adjustment plate and an adjustment assembly provided at one end of the X-axis adjustment plate and the Y-axis adjustment plate, the bottom of the X-axis adjustment plate is connected to the base plate via a first linear guide rail arranged transversely, the bottom of the Y-axis adjustment plate is connected to the X-axis adjustment plate via a second linear guide rail arranged longitudinally, the adjustment assembly comprises a first adjusting block provided on the base plate and a second adjusting block provided on the X-axis adjustment plate, the first adjusting block is provided with a first rotating knob connected to the second adjusting block, the second adjusting block is provided with a second rotating knob connected to the Y-axis adjustment plate, the first rotating knob and the second rotating knob are configured to be rotated in sequence to achieve horizontal adjustment of the lifting and rotating mechanism, the holding and ejecting mechanism includes a support arm, the top of the support arm is provided with a preheating ring, the bottom of the support arm is connected to the magnetic fluid dynamic seal, the inner top of the preheating ring is provided with a docking groove for holding a wafer, a push pin is slidably arranged on the support arm, a position limiting support is disposed at the bottom of the process chamber opposite to the push pin, and the lifting and rotating mechanism is configured to drive the support arm to lift and rotate.

The present disclosure provides a dynamic seal deposition apparatus for epitaxy, including:
a base plate;
a positioning adjustment mechanism provided above the base plate, the positioning adjustment mechanism including an X-axis adjustment plate, a Y-axis adjustment plate and an adjustment assembly;
a lifting and rotating mechanism provided above the positioning and adjusting mechanism, a magnetic fluid dynamic seal being provided above the lifting and rotating mechanism, and a process chamber being provided above the magnetic fluid dynamic seal; and
a holding and ejecting mechanism provided in the process chamber and including a support arm, the bottom of the support arm being connected to the magnetic fluid dynamic seal, the top of the support arm being used to hold the wafer, and the lifting and rotating mechanism being configured to drive the support arm to lift and rotate;
wherein the adjustment assembly is provided at one end of the X-axis adjustment plate and the Y-axis adjustment plate, and the adjustment assembly is configured to achieve the adjustment of the lifting and rotating mechanism in the horizontal direction.

### BRIEF DESCRIPTION OF THE DRAWINGS

FIG. 1 is a structural diagram of the dynamic seal deposition apparatus for epitaxy according to some embodiments of the present disclosure.

FIG. 2 is a cross-sectional view of the dynamic seal deposition apparatus for epitaxy according to some embodiments of the present disclosure.

FIG. 3 is a first perspective view of the positioning adjustment mechanism in FIG. 1.

FIG. 4 is a second perspective view of the positioning adjustment mechanism in FIG. 1.

FIG. 5 is a structural diagram of the first rotating knob and the second rotating knob in FIG. 1.

FIG. 6 is a structural diagram of the water-cooled sealing block in FIG. 1.

FIG. 7 is a cross-sectional view of the water-cooling sealing block in FIG. 1.

### LIST OF REFERENCE NUMERALS IN THE DRAWINGS

1—Second Annular Clamping Edge
2—Upper Clamping Ring
3—Intermediate Plate
4—Air Inlet Channel
5—Air Cavity
6—Lower Clamping Ring
7—First Annular Clamping Edge
8—Preheating Ring
9—Horizontal Part
10—Position Limiting Support
11—Inclined Part
12—Crossbeam
13—First Support Column
14—Linear Bearing
15—Guide Shaft
16—Motor Seat
17—Star coupling
18—Direct-Drive Rotary Motor
19—Mounting Seat
20—Magnetic Fluid Dynamic Seal
21—Adapter Block
22—Lifting Plate
23—Polygonal Clamping Column
24—Polygonal Inner Sleeve
25—Bellows
26—Water-Cooled Sealing Block
27—Annular Water Channel
28—Sealing Ring
29—Protrusion
30—Press Block
31—Air Outlet Channel
32—Lower Glass Cover
33—Docking Groove
34—Second Support Column
35—Upper Glass Cover
36—Wafer
37—Push Pin
38—Sliding Column
39—Support Arm Plate
40—Base Plate
41—Linear Electric Cylinder
42—Bracket
43—Detection Piece
44—First Photoelectric Sensor
45—Second Photoelectric Sensor
46—Third Photoelectric Sensor
47—Gate Valve
48—First Dial Indicator
49—First Through Hole
50—Fourth Fixing Block
51—First Locking Gap
52—First Adjusting Block
53—First Stop Screw
54—Extension Plate
55—Third Socket Head Cap Screw
56—Third Lock Nut
57—Second Rotating Knob
58—Second Stop Screw
59—X-Axis Adjustment Plate
60—Second Adjusting Block
61—First Rotating Knob
62—First U-Shaped Groove
63—Second Through Hole
64—Fifth Fixing Block
65—Second Locking Gap
66—Y-Axis Adjustment Plate
67—Second Threaded Hole
68—Second Dial Indicator
69—First Lock Nut
70—First Socket Head Cap Screw
71—First Fixing Block
72—Third Fixing Block
73—Fourth Socket Head Cap Screw
74—Fourth Lock Nut
75—First Linear Guide Rail
76—Second Fixing Block
77—Second Lock Nut
78—Second Socket Head Cap Screw
79—Second Linear Guide Rail
80—Externally Threaded Rod
81—Roller
82—Knob Head
83—Limit Post
84—Pressure Sensor
85—Vacuum Pump
86—Water Inlet
87—Air Inlet Pipe
88—Detection Pipe
89—Water Outlet

### DETAILED DESCRIPTION OF THE EMBODIMENTS

The present disclosure is further described below in conjunction with the accompanying drawings. The following embodiments are only used to more clearly illustrate the solutions of the present disclosure and are not intended to limit the scope of the present disclosure.

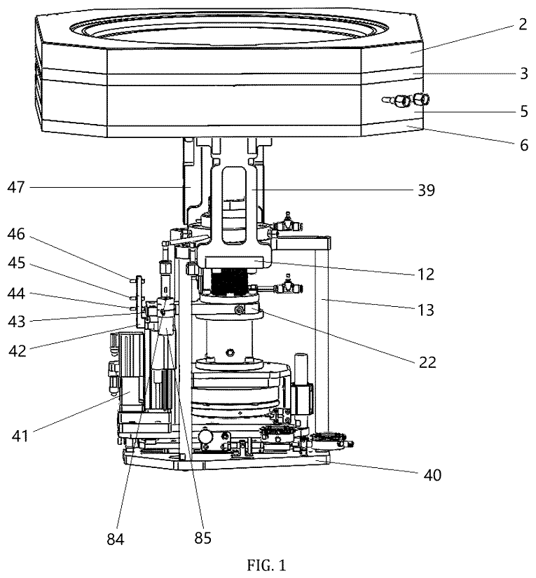

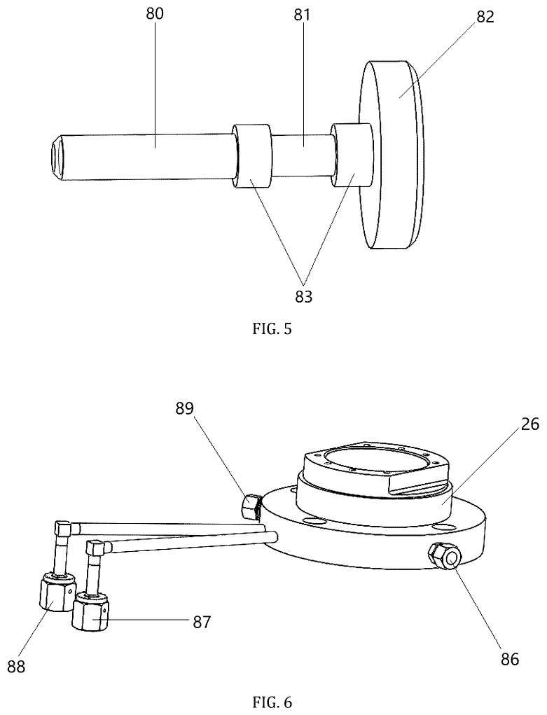

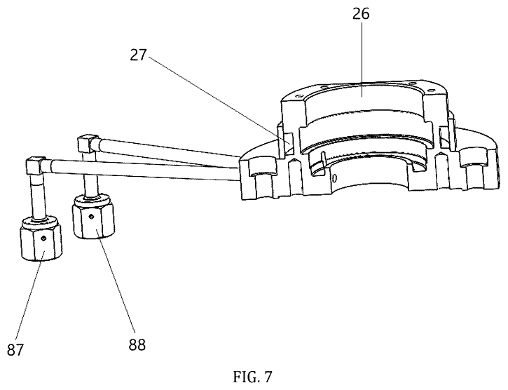

As shown in FIG. 1 to FIG. 7, the present disclosure provides a dynamic sealing deposition apparatus for epitaxy, including a base plate 40, and a positioning adjustment mechanism is provided above the base plate 40. The positioning adjustment mechanism is used for positioning adjustment in the horizontal direction. Specifically, the positioning adjustment mechanism includes an adjustment assembly, and the adjustment assembly includes a first adjusting block 52 and a second adjusting block 60. A transverse mounting groove is provided on the top of the base plate 40, and a first linear guide rail 75 is fixedly mounted in the transverse mounting groove by bolts. The top of the first linear guide rail 75 is fixedly connected to an X-axis adjustment plate 59 by bolts. Longitudinal mounting grooves are provided on both sides of the top of the X-axis adjustment plate 59, and a second linear guide rail 79 is fixedly mounted in the longitudinal mounting groove by bolts. The tops of the two second linear guide rails 79 are fixedly connected to a Y-axis adjustment plate 66 by bolts. In other words, the main functions of the first linear guide rail 75 and the two second linear guide rails 79 are to provide guidance and support. The linear guide rail is also referred to as slide rail and slider, that is, the linear guide rail can be understood as consisting of a slide rail and a slider. The slide rail is relatively stationary, and the slider can move back and forth along the slide rail. The slide rail in the first linear guide rail 75 can be fixed in the transverse mounting groove of the base plate 40 by bolts, and the top of the slider in the first linear guide rail 75 can be fixedly connected to the X-axis adjustment plate 59 by bolts. The slide rail in the second linear guide rail 79 can be fixed in the longitudinal mounting groove of the X-axis adjustment plate 59 by bolts, and the top of the slider in the second linear guide rail 79 can be fixedly connected to the Y-axis adjustment plate 66 by bolts. A first positioning notch is provided at one end of the X-axis adjustment plate 59, and the second adjusting block 60 is fixedly mounted in the first positioning notch by bolts. A first mounting groove is provided at the top of the base plate 40 near one end of the second adjusting block 60, and the first adjusting block 52 is fixedly mounted in the first mounting groove by bolts. A first U-shaped groove 62 is provided at the top of the first adjusting block 52, and the first rotating knob 61 is mounted in the first U-shaped groove 62. An extension plate 54 is integrally provided outwardly of the second adjusting block 60, and the first rotating knob 61 is threadedly connected to the extension plate 54. The end of the first adjusting block 52 away from the X-axis adjustment plate 59 is threadedly connected to the first stop screw 53, and the first stop screw 53 is arranged opposite to the first rotating knob 61. The second adjusting block 60 is provided with a second U-shaped groove on the side away from the first adjusting block 52, and the second rotating knob 57 is mounted in the second U-shaped groove. The second rotating knob 57 is threadedly connected to the Y-axis adjustment plate 66, and the top of the second adjusting block 60 is threadedly connected to the second stop screw 58. The second stop screw 58 is arranged opposite to the second rotating knob 57.

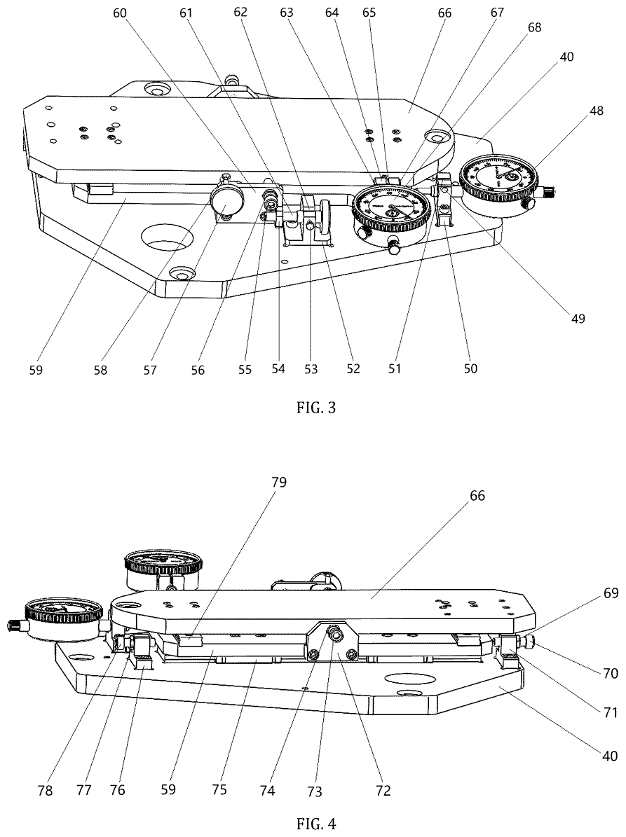

Referring to FIG. 3 and FIG. 5, in the embodiment of the present disclosure, the first rotating knob 61 and the second rotating knob 57 both include a roller 81, a knob head 82 and an externally threaded rod 80. Limit posts 83 are integrally provided at both ends of the roller 81. The knob head 82 is integrally provided with the limit post 83 on one side, and the externally threaded rod 80 is integrally provided with the limit post 83 on the other side. In other words, the first rotating knob 61 and the second rotating knob 57 both include a knob head 82, a roller 81 and an externally threaded rod 80 connected in sequence. The limit post 83 is connected between the knob head 82 and the roller 81, and between the roller 81 and the externally threaded rod 80. The roller 81 on the first rotating knob 61 is located in the first U-shaped groove 62, and the limit post 83 on the first rotating knob 61 is attached to the outer side of the first U-shaped groove 62, which is convenient for limiting the position of the roller 81 on the first rotating knob 61. The externally threaded column 80 on the first rotating knob 61 is threadedly connected to the extension plate 54, and the first stop screw 53 is arranged opposite to the roller 81 on the first rotating knob 61. The roller 81 on the second rotating knob 57 is located in the second U-shaped groove, and the limit post 83 on the second rotating knob 57 is attached to the outer side of the second U-shaped groove, which is convenient for limiting the position of the roller 81 on the second rotating knob 57. The externally threaded column 80 on the second rotating knob 57 is threadedly connected to the Y-axis adjustment plate 66, and the second stop screw 58 is arranged opposite to the roller 81 on the second rotating knob 57.

During adjustment, the knob head 82 on the first rotating knob 61 is first rotated to adjust the position of the X-axis adjustment plate 59 in the X-axis direction. Once adjustment is complete, the first stop screw 53 is rotated to abut against the roller 81 on the first rotating knob 61. The knob head 82 on the second rotating knob 57 is then rotated to adjust the position of the Y-axis adjustment plate 66 in the Y-axis direction. Once adjustment is complete, the second stop screw 58 is rotated to abut against the roller 81 on the second rotating knob 57. Adjustment in the horizontal X and Y directions not only allows the wafer 36 to be positioned in the center of the process chamber during installation and debugging, significantly improving deposition uniformity, but also allows the wafer 36 to be readjusted when its deposition position shifts to achieve optimal deposition effect. Furthermore, the first adjusting block 52 and the second adjusting block 60 are located at the same end, as shown in FIG. 3. That is, the adjustment assembly is located on the same side of the X-axis adjustment plate 59 and the Y-axis adjustment plate 66. This arrangement effectively improves operational convenience and reduces labor costs.

As shown in FIG. 4, the positioning adjustment mechanism also includes a positioning assembly, which includes a first fixing block 71 and a second fixing block 76. The top of the base plate 40 at the side of the X-axis adjustment plate 59 is provided with a second mounting groove, and the first fixing block 71 is fixedly mounted in the second mounting groove by bolts. The first socket head cap screw 70 is threadedly connected to the first fixing block 71. The first socket head cap screw 70 is arranged opposite to the X-axis adjustment plate 59. The first lock nut 69 is threadedly connected to the first socket head cap screw 70. In this embodiment, the first lock nut 69 is located on the side of the screw portion of the first socket head cap screw 70 close to the head of the first socket head cap screw 70, but is not limited to this. The first lock nut 69 can also be located on the side of the screw portion of the first socket head cap screw 70 away from the head of the first socket head cap screw 70.

A third mounting groove is provided at the top of the base plate 40 on the other side of the X-axis adjustment plate 59, and the second fixing block 76 is fixedly mounted in the third mounting groove by bolts. The second socket head cap screw 78 is threadedly connected to the second fixing block 76 and the second socket head cap screw 78 is arranged opposite to the X-axis adjustment plate 59. The second lock nut 77 is threadedly connected to the second socket head cap screw 78. In this embodiment, the second lock nut 77 is located on the side of the screw of the second socket head cap screw 78 close to the head of the second socket head cap screw 78, but is not limited to this. The second lock nut 77 can also be located on the side of the screw of the second socket head cap screw 78 away from the head of the second socket head cap screw 78. The third socket head cap screw 55 is threadedly connected to the second adjusting block 60, and the third socket head cap screw 55 is arranged opposite to the Y-axis adjustment plate 66. The third lock nut 56 is threadedly connected to the third socket head cap screw 55. In this embodiment, the third lock nut 56 is located at the end of the screw portion of the third socket head cap screw 55 close to the head of the third socket head cap screw 55, but is not limited to this. The third lock nut 56 can also be located at the end of the screw portion of the third socket head cap screw 55 away from the head of the third socket head cap screw 55.

A second positioning notch is provided at one end of the X-axis adjustment plate 59 away from the second adjusting block 60, and the third fixing block 72 is fixedly mounted at the second positioning notch by bolts. The fourth socket head cap screw 73 is threadedly connected to the third fixing block 72, and the fourth socket head cap screw 73 is arranged opposite to the Y-axis adjustment plate 66. The fourth lock nut 74 is threadedly connected to the fourth socket head cap screw 73. In this embodiment, the fourth lock nut 74 is located at the end of the screw portion of the fourth socket head cap screw 73 close to the head of the fourth socket head cap screw 73, but is not limited to this. The fourth lock nut 74 can also be located at the end of the screw portion of the fourth socket head cap screw 73 away from the head of the fourth socket head cap screw 73.

In application, after the adjustment of the X-axis adjustment plate 59 is completed, the first socket head cap screw 70 is first rotated to make the first socket head cap screw 70 abut against the X-axis adjustment plate 59, and then the first lock nut 69 is rotated to tighten the first lock nut 69 to the first fixing block 71, and then the second socket head cap screw 78 is rotated to make the second socket head cap screw 78 abut against the X-axis adjustment plate 59, and finally the second lock nut 77 is rotated to tighten the second lock nut 77 to the second fixing block 76 to complete the positioning of the X-axis adjustment plate 59. After the adjustment of the Y-axis adjustment plate 66 is completed, the third socket head cap screw 55 is first rotated to make the third socket head cap screw 55 abut against the Y-axis adjustment plate 66, and then rotate the third lock nut 56 to tighten it with the second adjusting block 60, and then the fourth socket head cap screw 73 is rotated to make the fourth socket head cap screw 73 abut against the Y-axis adjustment plate 66, and finally rotate the fourth lock nut 74 so that the fourth lock nut 74 is tightened with the third fixing block 72 to complete the positioning of the Y-axis adjustment plate 66.

As shown in FIG. 3 and FIG. 4, a fourth mounting groove is provided at the top of the base plate 40 near the second fixing block 76, and the fourth fixing block 50 is fixedly mounted in the fourth mounting groove by bolts. A first clamping hole is provided on the fourth fixing block 50, and the first dial indicator 48 is clamped in the first clamping hole. The probe of the first dial indicator 48 abuts against the X-axis adjustment plate 59. The first locking gap 51 is provided at the top of the fourth fixing block 50, and the first locking gap 51 is communicated with the first clamping hole. The first through hole 49 is provided at one end of the fourth fixing block 50, and a first threaded hole is provided at the other end. The first threaded hole and the first through hole 49 are arranged opposite to each other, and the first threaded hole and the first through hole 49 are respectively communicated with the first locking gap 51. A first locking bolt is provided in the first through hole 49. When tightening, the first locking bolt is threadedly connected to the first threaded hole to make the first locking bolt pass through the first locking gap 51, so that at least a part of the first dial indicator 48 is confined within the first clamping hole on one side of the first locking bolt.

A third positioning notch is provided at the top of the X-axis adjustment plate 59 near one end of the first adjusting block 52, and the fifth fixing block 64 is mounted in the third positioning notch. A second clamping hole is provided on the fifth fixing block 64, and the second dial indicator 68 is clamped in the second clamping hole. The probe of the second dial indicator 68 abuts against the Y-axis adjustment plate 66. The second locking gap 65 is provided on the top of the fifth fixing block 64, and the second locking gap 65 is communicated with the second clamping hole. The second through hole 63 is provided on one side of the fifth fixing block 64, and the second threaded hole 67 is provided on the other side. The second threaded hole 67 is arranged opposite to the second through hole 63, and the second threaded hole 67 and the second through hole 63 are respectively communicated with the second locking gap 65. A second locking bolt is provided in the second through hole 63. When tightening, the second locking bolt is threadedly connected to the second threaded hole 67 to make the second locking bolt pass through the second locking gap 65, so that at least a part of the second dial indicator 68 is confined within the second clamping hole on one side of the second locking bolt.

By providing the first dial indicator 48 and the second dial indicator 68, the offset position of the X-axis adjustment plate 59 and the Y-axis adjustment plate 66 can be accurately measured, and the deposition position of the wafer 36 can be recorded. When the deposition position of the wafer 36 is shifted, the deposition position of the wafer 36 can be readjusted according to the positions recorded by the first dial indicator 48 and the second dial indicator 68 to achieve the best deposition effect.

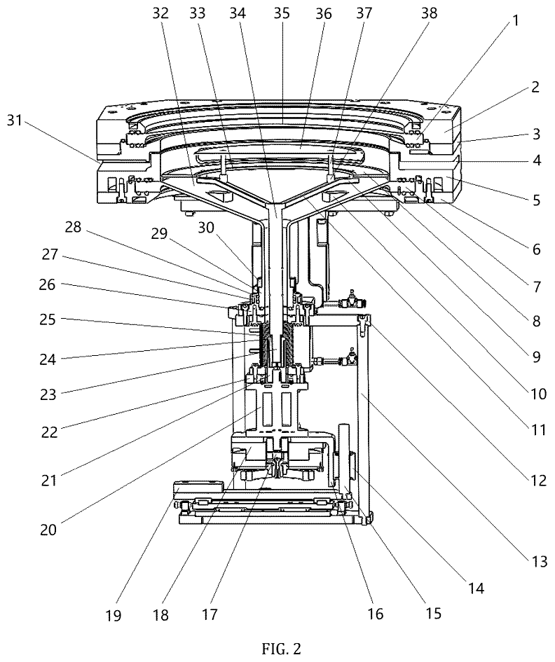

Referring to FIG. 1 and FIG. 2, a lifting and rotating mechanism is provided above the positioning and adjusting mechanism. Specifically, the lifting and rotating mechanism includes a direct-drive rotary motor 18. One side of the Y-axis adjustment plate 66 is fixedly connected to the mounting seat 19 by bolts. The top of the mounting seat 19 is fixedly connected to the linear electric cylinder 41 by bolts. The output end of the linear electric cylinder 41 is fixedly connected to the lifting plate 22 by bolts. The bottom of the lifting plate 22 is fixedly connected to the magnetic fluid dynamic seal 20 by bolts. The magnetic fluid dynamic seal 20 is fixedly connected to the output end of the direct-drive rotary motor 18 through the star coupling 17. The magnetic fluid dynamic seal 20 and the direct-drive rotary motor 18 are fixedly connected to the motor seat 16 by bolts. The Y-axis adjustment plate 66 is fixedly connected to the guide shaft 15 by bolts on the side away from the linear electric cylinder 41. The motor seat 16 is fixedly connected to the linear bearing 14 on the side close to the guide shaft 15 by bolts, wherein the linear bearing is slidably connected to the guide shaft 15. The linear electric cylinder 41 is fixedly connected to the bracket 42 by bolts. The bracket 42 is sequentially mounted with the first photoelectric sensor 44, the second photoelectric sensor 45, and the third photoelectric sensor 46 along the height direction. That is, the second photoelectric sensor 45 is located below the third photoelectric sensor 46, and the first photoelectric sensor 44 is located below the second photoelectric sensor 45. The lifting plate 22 is fixedly connected to the detection piece 43 on the side close to the bracket 42 by a hexalobular socket pan head screw.

In this embodiment, in the ejection state, the detection piece 43 is sensed by the first photoelectric sensor 44; in the initial state, the detection piece 43 is sensed the second photoelectric sensor 45; and in the processing state, the detection piece 43 is sensed by the third photoelectric sensor 46. The lifting and rotating mechanism can not only achieve the rotation process of the wafer 36, but also achieve the adjustment under different states, thereby improving the practicality of the wafer 36 processing. In this embodiment, the second photoelectric sensor 45 is located at the end of the bracket 42 close to the first photoelectric sensor 44. In the initial state, the positioning detection for the detection piece 43 and the second photoelectric sensor 45 need to be performed. The positioning method is that the detection piece 43 is positioned and searched between the first photoelectric sensor 44 and the third photoelectric sensor 46 by moving downward and then upward. Therefore, the second photoelectric sensor 45 is located at the end of the bracket 42 close to the first photoelectric sensor 44, which can effectively shorten the positioning detection time and reduce costs.

A process chamber is provided above the lifting and rotating mechanism. Specifically, the process chamber includes a lower glass cover 32, an upper glass cover 35 and an air cavity 5. The top of the lifting plate 22 is fixedly connected to the bellows 25 by a hexalobular socket head cap screw. The bellows 25 is arranged opposite to the magnetic fluid dynamic seal 20. The top of the bellows 25 is fixedly connected to a water-cooled sealing block 26 by a hexalobular socket head cap screw. The top of the water-cooled sealing block 26 is fixedly connected to the press block 30 by a hexalobular socket head cap screw. The bottom of the lower glass cover 32 is provided outwardly with a protrusion 29. The protrusion 29 is clamped between the water-cooled sealing block 26 and the press block 30. The bottom of the air cavity 5 is fixedly connected to the lower clamping ring 6 by a hexalobular socket head cap screw. The outer side of the top of the air cavity 5 is fixedly connected to the intermediate plate 3 by a hexalobular socket head cap screw. The top of the intermediate plate 3 is fixedly connected to the upper clamping ring 2 by a hexalobular socket head cap screw. The top of the lower glass cover 32 is integrally provided outwardly with the first annular clamping edge 7, and the first annular clamping edge 7 is provided between the air cavity 5 and the lower clamping ring 6. The upper glass cover 35 is integrally provided with the second annular clamping edge 1 outward, and the second annular clamping edge 1 is provided between the air cavity 5 and the upper clamping ring 2. The air inlet channel 4 is provided on one side of the air cavity 5, and the air outlet channel 31 is provided on the other side. The air inlet channel 4 and the air outlet channel 31 are arranged opposite to each other. One end of the air cavity 5 is provided a push port, and the gate valve 47 is mounted at the push port. At the start of operation, the gate valve 47 is opened, and an external mechanical arm sends the wafer 36 into the push port. During the deposition process, the gate valve 47 is closed. After the deposition process is completed, the gate valve 47 is opened, and the external mechanical arm moves the wafer 36 out of the push port.

The process chamber not only accommodates the lifting and rotating mechanism to adjust the deposition position of the wafer 36 within the process chamber, but also provides a sealed process space, saving space costs. The intermediate plate 3 is located between the air cavity 5 and the upper clamping ring 2. Since the air cavity 5 and the upper clamping ring 2 require frequent installation and removal, during installation and removal, the air cavity 5 and the intermediate plate 3 are kept fixedly connected, and only the upper clamping ring 2 and the intermediate plate 3 need to be installed and removed. This effectively avoids excessive wear of the air cavity 5 due to long-term replacement of the air cavity 5 and the upper clamping ring 2, further extending the service life of the air cavity 5.

In this embodiment, the two ends of the bottom of the lower clamping ring 6 are fixedly connected to the support arm plates 39 by hexalobular socket head cap screws, and the support arm plates 39 are fixedly connected to the crossbeam 12 by hexalobular socket head cap screws. The crossbeam 12 is provided with an opening for allowing the bellows 25 to pass through. The crossbeam 12 is fixedly connected to the bottom of the water-cooled sealing block 26 by hexalobular socket head cap screws. The bottom of the crossbeam 12 is fixedly connected to the first support column 13 by hexalobular socket head cap screws, and the bottom of the first support column 13 is threadedly connected to the base plate 40.

A holding and ejecting mechanism is provided in the process chamber, and the lifting and rotating mechanism is used to lift and rotate the holding and ejecting mechanism. Specifically, the holding and ejecting mechanism includes the polygonal inner sleeve 24, a support arm and the preheating ring 8. The support arm includes the second support column 34. The bottom of the second support column 34 is provided with the polygonal clamping column 23, which is arranged in the polygonal inner sleeve 24. The polygonal inner sleeve 24 is fixedly connected to the magnetic fluid dynamic seal 20 through the adapter block 21. The top of the second support column 34 is integrally provided outwardly with a plurality of support claws at equal angles. The support claws include the inclined portion 11 and the horizontal portion 9. One end of the inclined portion 11 is integrally provided with the support arm, and the other end is integrally provided with the horizontal portion 9. The top of the horizontal portion 9 is connected with the preheating ring 8 through a support pin. The top of the inclined portion 11 is integrally provided with a sliding column 38. The sliding column 38 and the inclined portion 11 are correspondingly provided with sliding holes, and the push pin 37 is slidably connected in the sliding hole.

It should be noted that a slot is provided at the top of the sliding column 38, and a latching portion is integrally provided at the top of the push pin 37 to engage the slot. When the sliding column 38 rises above the height of the push pin 37, the sliding column 38 drives the push pin 37 upward. The wafer 36 may be placed on top of the push pin 37. The position limiting support 10 is integrally provided on the inner wall of the lower glass cover 32, and the position limiting support is provided opposite to the push pin 37. The docking groove 33 for receiving the wafer 36 is defined at the inner top of the preheating ring 8. The top of the sliding column 38 is not higher than the bottom of the docking groove 33, ensuring that the wafer 36 is held within the docking groove 33. The holding and ejecting mechanism, combined with the lifting and rotating mechanism, not only enables the deposition process for the wafer 36 but also allows the wafer 36 to be detached from the preheating ring 8 during placement and removal of the wafer 36, effectively preventing minor hard collisions between the wafer 36 and the preheating ring 8 that could damage the wafer 36, and significantly improving the deposition quality of the wafer 36.

In the application, in the initial state, the detection piece 43 is sensed by the second photoelectric sensor 45. When the dynamic seal apparatus for epitaxy works, the detection piece 43 is sensed by the first photoelectric sensor 44, and the linear electric cylinder 41 drives the support arm to move downward. The position limiting support 10 makes the push pin 37 in the ejection state. The gate valve 47 is opened. The external mechanical arm sends the wafer 36 to the top of the push pin 37 and then slowly descends, so that the wafer 36 is placed on the push pin 37. Then the external mechanical arm stops descending and moves outward. The gate valve 47 is closed, the detection piece 43 is sensed by the third photoelectric sensor 46, and the linear electric cylinder 41 drives the support arm to move upward, so that the wafer 36 is placed in the docking groove 33 and moves upward to the air inlet channel 4 and the air outlet channel 31. The direct-drive rotary motor 18 drives the support arm to rotate at a constant speed. The reaction gas is introduced into the air inlet channel 4 to deposit on the upper surface of the wafer 36. The reaction gas is discharged through the air outlet channel 31. After the deposition is completed, the detection piece 43 is sensed by the first photoelectric sensor 44, and the linear electric cylinder 41 drives the support arm to move downward. The push pin 37 separates the wafer 36 and the preheating ring 8. The gate valve 47 opens, and the external mechanical arm extends to the bottom of the wafer 36, lifts the wafer 36 and moves it out of the push port. The gate valve 47 is closed, the detection piece 43 is sensed by the second photoelectric sensor 45, and the initial state is returned.

In this embodiment, a sealing ring 28 is provided between the protrusion 29 and the water-cooled sealing block 26, and a water inlet 86 and a water outlet 89 are provided on the outside of the water-cooled sealing block 26, an annular water channel 27 is connected between the water inlet 86 and the water outlet 89. The setting of the annular water channel 27 can effectively prevent the sealing ring 28 from hardening under high temperature conditions, thereby effectively improving the service life of the sealing ring 28. An air inlet pipe 87 and a detection pipe 88 are also provided on the outside of the water-cooled sealing block 26. The air inlet pipe 87 is communicated with the process chamber. Before the dynamic seal apparatus for epitaxy operates, the air inlet channel 4 and the air inlet pipe 87 simultaneously introduce reactive gas into the process chamber, which can effectively remove the air in the process chamber, thereby not only improving the exhaust efficiency but also further improving the deposition effect under the process state. The detection line 88 is communicated with a connection part between the protrusion 29 and the water-cooled sealing block 26. The detection line 88 is externally connected to a pressure sensor 84. A vacuum pump 85 is mounted at the end of the pressure sensor 84 away from the detection line 88. Before the air is exhausted, the vacuum pump 85 is started to facilitate the detection of the airtightness between the protrusion 29 and the water-cooled sealing block 26 through the pressure sensor 84. In addition, sealing rings 28 are provided between the water-cooled sealing block 26 and the crossbeam 12, between the lifting plate 22 and the bellows 25, between the lifting plate 22 and the magnetic fluid dynamic seal 20, between the air cavity 5 and the first annular clamping edge 7, between the first annular clamping edge 7 and the lower clamping ring 6, between the upper clamping ring 2 and the second annular clamping edge 1, between the second annular clamping edge 1 and the air cavity 5, and between the air cavity 5 and the upper clamping ring 2.

The above is only a preferred embodiment of the present disclosure. It should be noted that for the persons skilled in the art, improvements and modifications can be made without departing from the principles of the present disclosure. These improvements and modifications should also be regarded as within the scope of the present disclosure.

What is claimed is:

1. A dynamic sealing deposition apparatus for epitaxy, comprising a base plate, a positioning adjustment mechanism provided above the base plate, a lifting and rotating mechanism provided above the positioning adjustment mechanism, a magnetic fluid dynamic seal provided above the lifting and rotating mechanism, a process chamber provided above the magnetic fluid dynamic seal, and a holding and ejecting mechanism provided in the process chamber,
wherein the positioning adjustment mechanism comprises an X-axis adjustment plate, a Y-axis adjustment plate and an adjustment assembly provided at one end of the X-axis adjustment plate and the Y-axis adjustment plate, a bottom of the X-axis adjustment plate being connected to the base plate via a first linear guide rail arranged transversely, and a bottom of the Y-axis adjustment plate being connected to the X-axis adjustment plate via a second linear guide rail arranged longitudinally,
wherein the adjustment assembly comprises a first adjusting block provided on the base plate and a second adjusting block provided on the X-axis adjustment plate, the first adjusting block being provided with a first rotating knob connected to the second adjusting block, and the second adjusting block being provided with a second rotating knob connected to the Y-axis adjustment plate, wherein the first rotating knob and the second rotating knob are configured to be rotated in sequence to achieve horizontal adjustment of the lifting and rotating mechanism,
wherein the holding and ejecting mechanism comprises a support arm, the top of the support arm being provided with a preheating ring, the bottom of the support arm being connected to the magnetic fluid dynamic seal, the inner top of the preheating ring being provided with a docking groove for holding a wafer, a push pin being slidably arranged on the support arm, and a position limiting support being disposed at the bottom of the process chamber opposite to the push pin, wherein the lifting and rotating mechanism is configured to drive the support arm to lift and rotate.

2. The dynamic sealing deposition apparatus for epitaxy according to claim 1, wherein a first U-shaped groove is provided on the top of the first adjusting block, the first rotating knob is mounted in the first U-shaped groove, an extension plate is outwardly provided on the second adjusting block, the first rotating knob is connected to the extension plate, a first stop screw is provided at one end of the first adjusting block, the first stop screw is arranged opposite to the first rotating knob, a second U-shaped groove is provided on one side of the second adjusting block, the second rotating knob is provided in the second U-shaped groove, a second stop screw is provided on the top of the second adjusting block, and the second stop screw is arranged opposite to the second rotating knob.

3. The dynamic sealing deposition apparatus for epitaxy according to claim 2, wherein the first rotating knob and the second rotating knob both comprise a roller, a knob head and an externally threaded rod, each end of the roller is connected to a limit post, the knob head is connected to the limit post at one end, the externally threaded rod is connected to the limit post at the other end, the roller on the first rotating knob is arranged in the first U-shaped groove, the limit post on the first rotating knob is attached to an outer side of the first U-shaped groove, the externally threaded rod on the first rotating knob is connected to the extension plate, the first stop screw is arranged opposite to the roller on the first rotating knob, the roller on the second rotating knob is arranged in the second U-shaped groove, the limit post on the second rotating knob is attached to an outer side of the second U-shaped groove, the externally threaded rod on the second rotating knob is connected to the Y-axis adjustment plate, and the second stop screw is arranged opposite to the roller on the second rotating knob.

4. The dynamic sealing deposition apparatus for epitaxy according to claim 2, wherein the positioning adjustment mechanism further comprises a positioning assembly comprising a first fixing block and a second fixing block, the first fixing block being mounted on the base plate on one side of the X-axis adjustment plate, the first fixing block being provided with a first socket head cap screw arranged opposite to the X-axis adjustment plate, the first socket head cap screw being connected to a first lock nut for limiting position of the first socket head cap screw, the second fixing block being mounted on the base plate on the other side of the X-axis adjustment plate, the second fixing block being provided with a second socket head cap screw arranged opposite to the X-axis adjustment plate, the second socket head cap screw being connected to a second lock nut for limiting position of the second socket head cap screw, the second adjusting block being provided with a third socket head cap screw arranged opposite to the Y-axis adjustment plate, the third socket head cap screw being connected to a third lock nut for limiting position of the third socket head cap screw, the X-axis adjustment plate being mounted with a third fixing block at one end away from the second adjusting block, the third fixing block being provided with a fourth socket head cap screw arranged opposite to the Y-axis adjustment plate, and the fourth socket head cap screw being connected to a fourth lock nut for limiting position of the fourth socket head cap screw.

5. The dynamic sealing deposition apparatus for epitaxy according to claim 4, wherein a fourth fixing block is mounted on the side of the base plate close to the second fixing block, a first clamping hole is provided on the fourth fixing block, a first dial indicator is clamped in the first clamping hole, a probe of the first dial indicator abuts against the X-axis adjustment plate, a first locking gap is provided on the top of the fourth fixing block, the first locking gap is communicated with the first clamping hole, a first through hole is provided at one end of the fourth fixing block and a first threaded hole is provided at the other end, the first threaded hole is arranged opposite to the first through hole and the first threaded hole and the first through hole are respectively communicated with the first locking gap, a first locking bolt is provided in the first through hole, the first locking bolt is connected to the first threaded hole, a fifth fixing block is mounted on one end of the X-axis adjustment plate near the first adjusting block, the fifth fixing block is provided with a second clamping hole, and a second dial indicator is clamped in the second clamping hole, a probe of the second dial indicator abuts against the Y-axis adjustment plate, a second locking gap is provided on the top of the fifth fixing block, and the second locking gap is communicated with the second clamping hole, a second through hole is provided on one side of the fifth fixing block and a second threaded hole is provided on the other side, the second threaded hole and the second through hole are arranged opposite to each other and the second threaded hole and the second through hole are respectively communicated with the second locking gap, a second locking bolt is provided in the second through hole, and the second locking bolt is connected with the second threaded hole.

6. The dynamic sealing deposition apparatus for epitaxy according to claim 2, wherein the lifting and rotating mechanism includes a direct-drive rotary motor, a mounting seat is provided on one side of the Y-axis adjustment plate, a linear electric cylinder is provided on the top of the mounting seat, the output end of the linear electric cylinder is connected to a lifting plate, the bottom of the lifting plate is connected to a magnetic fluid dynamic seal, the magnetic fluid dynamic seal is connected to the output end of the direct-drive rotary motor through a star coupling, a motor seat is connected between the magnetic fluid dynamic seal and the direct-drive rotary motor, the Y-axis adjustment plate is connected to a guide shaft on a side away from the linear electric cylinder, the motor seat, on the side close to the guide shaft, is connected to a linear bearing slidably connected to the guide shaft, a bracket is connected to the linear electric cylinder, the bracket is sequentially mounted with a first photoelectric sensor, a second photoelectric sensor and a third photoelectric sensor along the height direction, and a detection piece is connected to the lifting plate on the side close to the bracket, wherein in an ejection state, the detection piece is sensed by the first photoelectric sensor, in an initial state, the detection piece is sensed by the second photoelectric sensor, and in a process state, the detection piece is sensed the third photoelectric sensor.

7. The dynamic sealing deposition apparatus for epitaxy according to claim 6, wherein the process chamber comprises a lower glass cover, an upper glass cover and an air cavity, the top of the lifting plate is connected with a bellows arranged opposite to the magnetic fluid dynamic seal, the top of the bellows is connected with a water-cooled sealing block, the top of the water-cooled sealing block is connected with a press block, the bottom of the lower glass cover is provided outwardly with a protrusion, the protrusion is clamped between the water-cooled sealing block and the press block, the bottom of the air cavity is connected with a lower clamping ring, an outer side of the top of the air cavity is connected with an intermediate plate, the top of the intermediate plate is connected with an upper clamping ring, the top of the lower glass cover is provided outwardly with a first annular clamping edge, the first annular clamping edge is provided between the air cavity and the lower clamping ring, the upper glass cover is provided outwardly with a second annular clamping edge, and the second annular clamping edge is provided between the air cavity and the upper clamping ring.

8. The dynamic sealing deposition apparatus for epitaxy according to claim 7, wherein two ends of the bottom of the lower clamping ring are connected to support arm plates, a crossbeam is connected between the support arm plates, the crossbeam is provided with an opening that allows the bellows to pass through, the crossbeam is connected to the bottom of the water-cooled sealing block, the bottom of the crossbeam is connected to a first support column, and the first support column is connected to the base plate.

9. The dynamic sealing deposition apparatus for epitaxy according to claim 7, wherein the holding and ejecting mechanism further comprises a polygonal inner sleeve, the support arm includes a second support column, the bottom of the second support column is provided with a polygonal clamping column arranged in the polygonal inner sleeve, the polygonal inner sleeve is connected to the magnetic fluid dynamic seal through an adapter block, the top of the second support column is provided outwardly with a plurality of support claws at equal angles, the support claws comprises an inclined portion and a horizontal portion, one end of the inclined portion is connected to the support arm and the other end is connected to the horizontal portion, the top of the horizontal portion is connected to the preheating ring through a support pin, the top of the inclined portion is provided with a sliding column, the sliding column and the inclined portion are correspondingly provided with sliding holes, the push pin is provided in the sliding hole, the position limiting support is provided on the inner wall of the lower glass cover, and the top of the sliding column is not higher than the bottom of the docking groove.

10. The dynamic sealing deposition apparatus for epitaxy according to claim 7, wherein a sealing ring is provided between the protrusion and the water-cooled sealing block, a water inlet and a water outlet are provided on the outside of the water-cooled sealing block, an annular water channel is connected between the water inlet and the water outlet, an air inlet pipe and a detection pipe are also provided on the outside of the water-cooled sealing block, the air inlet pipe is communicated with the process chamber, the detection pipe is communicated with a connection part between the protrusion and the water-cooled sealing block, a pressure sensor is externally connected to the detection pipe, and a vacuum pump is mounted at one end of the pressure sensor away from the detection pipe.

11. A dynamic seal deposition apparatus for epitaxy, comprising:
a base plate;
a positioning adjustment mechanism provided above the base plate, the positioning adjustment mechanism comprising an X-axis adjustment plate, a Y-axis adjustment plate and an adjustment assembly;
a lifting and rotating mechanism provided above the positioning and adjusting mechanism, a magnetic fluid dynamic seal being provided above the lifting and rotating mechanism, and a process chamber being provided above the magnetic fluid dynamic seal; and
a holding and ejecting mechanism disposed inside the process chamber and comprising a support arm, a bottom of the support arm being connected to the magnetic fluid dynamic seal, a top of the support arm being used to hold the wafer, and the lifting and rotating mechanism being configured to drive the support arm to lift and rotate;
wherein the adjustment assembly is provided at one end of the X-axis adjustment plate and the Y-axis adjustment plate, and the adjustment assembly is configured to achieve adjustment of the lifting and rotating mechanism in a horizontal direction.

12. The dynamic seal deposition apparatus for epitaxy according to claim 11, wherein a bottom of the X-axis adjustment plate is connected to the base plate via a first linear guide rail arranged transversely, and a bottom of the Y-axis adjustment plate is connected to the X-axis adjustment plate via a second linear guide rail arranged longitudinally.

13. The dynamic seal deposition apparatus for epitaxy according to claim 11, wherein the adjustment assembly comprises:
a first adjusting block provided on the base plate and the X-axis adjustment plate, wherein the first adjusting block is provided with a first rotating knob; and
a second adjusting block connected to the first rotating knob, wherein the second adjusting block is provided with a second rotating knob, and the second rotating knob is connected to the Y-axis adjustment plate; wherein the first rotating knob and the second rotating knob are configured to be rotated in sequence to achieve horizontal adjustment of the lifting and rotating mechanism.

14. The dynamic seal deposition apparatus for epitaxy according to claim 11, wherein a preheating ring is provided on a top of the support arm, a docking groove for holding a wafer is provided on the inner top of the preheating ring, and a push pin is slidably provided on the support arm; and
wherein a position limiting support is disposed at a bottom of the process chamber opposite to the push pin.
